(19) United States
(12) Patent Application Publication
(10) Pub. No.: US 2011/0030776 A1
(43) Pub. Date: Feb. 10, 2011

(54) Photovoltaic device back contact

(76) Inventors: Benyamin Buller, Sylvania, OH (US); Akhlesh Gupta, Sylvania, OH (US); Syed Zafar, Perrysburg, OH (US)

Correspondence Address: STEPTOE & JOHNSON LLP, 1330 CONNECTICUT AVENUE, N.W., WASHINGTON, DC, 20036, US

(21) Appl. No.: 12/805,626

(22) Filed: Aug. 10, 2010

Related U.S. Application Data
(60) Provisional application No. 61/232,767, filed on Aug. 10, 2009.

(51) Int. Cl. H01L 31/0232; H01L 31/18

(52) U.S. Cl. 136/256; 438/69; 257/E31.127

(57) ABSTRACT

A photovoltaic device back contact is disclosed. The back contact can include an indium nitride.

### CLAIM OF PRIORITY

This application claims priority to U.S. Provisional Patent Application No. 61/232,767, filed on Aug. 10, 2009, which is incorporated by reference in its entirety.

### TECHNICAL FIELD

This invention relates to a photovoltaic device with an improved back contact.

### BACKGROUND

In order to electrically connect a photovoltaic device, the back contact layer can include metal. For thin film solar cells, the metal back contact can have a back-contact barrier effect. The presence of a back-contact barrier can affect the current-voltage characteristics of thin-film solar cells primarily by impeding hole transport, a current-limiting effect commonly referred to as “rollover.” As a result, it can significantly reduce the photovoltaic device performance.

### DESCRIPTION OF DRAWINGS

FIG. 1 is a schematic of a band diagram of a photovoltaic device having multiple layers and a metal back contact layer.

FIG. 2 is a schematic of a photovoltaic device having multiple layers and a new back contact.

FIG. 3 is a schematic of a photovoltaic device having multiple layers and a new back contact.

FIG. 4 is a schematic of a band diagram of a photovoltaic device having multiple layers and a new back contact.

### DETAILED DESCRIPTION

In order to electrically connect a photovoltaic device, the back contact layer can include metal. A photovoltaic device having an improved back contact is developed to lower the back-contact barrier and result in enhanced device performance.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current which, combined with the resulting voltage from the electric field, creates power. The result is the conversion of photon energy into electric power. In order to electrically connect a photovoltaic device, the back contact layer can include metal. A metallic contact can result in a back-contact barrier that can limit current flow.

In one aspect, a photovoltaic device can include a substrate, a transparent conductive oxide layer adjacent to the substrate, a semiconductor window layer adjacent to the transparent conductive oxide layer, a semiconductor absorber layer adjacent to the semiconductor window layer, and a back contact layer adjacent to the semiconductor absorber layer, wherein the back contact layer can include an indium nitride. The device can have a reduced back-contact barrier effect compared to a metal back contact. The photovoltaic device can further include a back support adjacent to the back contact. The substrate can include a glass. The semiconductor window layer can include a cadmium sulfide. The semiconductor absorber layer can include a cadmium telluride. The transparent conductive oxide layer can include a zinc oxide. The transparent conductive oxide layer can include a tin oxide. The transparent conductive oxide layer can include a cadmium stannate.

In another aspect, a method of manufacturing a photovoltaic device can include the steps of depositing a transparent conductive oxide layer adjacent to a substrate, depositing a semiconductor window layer adjacent to the transparent conductive oxide layer, depositing a semiconductor absorber layer adjacent to the semiconductor window layer, and depositing a back contact layer adjacent to the semiconductor absorber layer, wherein the back contact layer includes an indium nitride. The device can have a reduced back-contact barrier effect compared to metal back contact. The method can further include attaching a back support adjacent to the back contact layer. The substrate can include a glass. The step of depositing the back contact layer can include evaporation. The step of depositing the back contact layer can include activation reactive evaporation. The step of depositing the back contact layer can include chemical vapor deposition. The step of depositing the back contact layer can include low-pressure organometallic chemical vapor deposition. The step of depositing the back contact layer can include sputtering. The step of depositing the back contact layer can include reactive sputtering. The semiconductor window layer can include a cadmium sulfide. The semiconductor absorber layer can include a cadmium telluride. The transparent conductive oxide layer can include a zinc oxide. The transparent conductive oxide layer can include a tin oxide. The transparent conductive oxide layer can include a cadmium stannate.

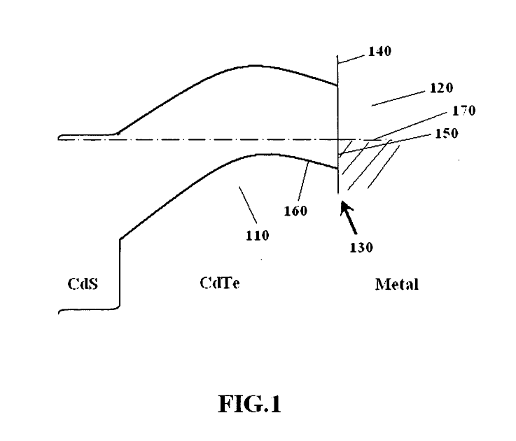

Referring to FIG. 1, a photovoltaic device can have a cadmium sulfide layer as a semiconductor window layer and a cadmium telluride layer as a semiconductor absorber layer. Since the cadmium telluride used in solar cells is a relatively wide band-gap p-type semiconductor, a large Schottky barrier for holes in region 130 that may limit current flow can be formed on metal/p-type semiconductor interface 140 between cadmium telluride layer 110 and metallic back contact 120. Height of Schottky barrier or back contact barrier 150 is the difference of valence band maximum 160 of cadmium telluride and metal Fermi level 170. In a circuit model, the back contact forms a diode of opposite polarity to the primary junction. It can limit current flow in a manner often referred to as the “rollover” effect. As a result, the “rollover” effect can reduce the photovoltaic device performance.

A photovoltaic device can include a semiconductor window including cadmium sulfide and a semiconductor absorber layer including cadmium telluride. A photovoltaic device can have a back contact layer which includes a back contact material which can reduce the back-contact barrier compared to the barrier formed with a metal back contact. The back contact material can include any suitable barrier reducing material. For example, the back contact material can include an indium-containing material such as indium nitride or any other suitable material.

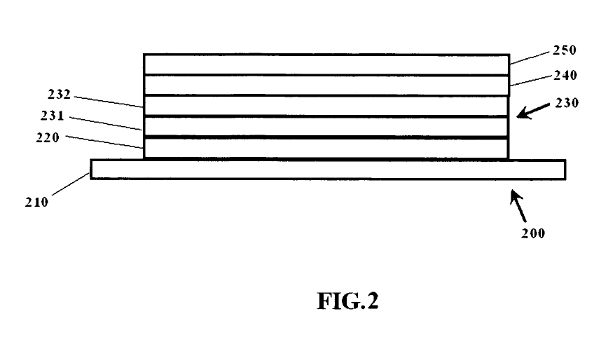

Referring to FIG. 2, a photovoltaic device 200 can include a transparent conductive oxide layer 220 deposited adjacent to a substrate 210. Transparent conductive oxide layer 220 can be deposited on substrate 210 by sputtering or evaporation or any other appropriate method. Substrate 210 can include any suitable substrate material, including glass, such as soda-lime glass. Transparent conductive oxide layer 220 can include any suitable transparent conductive oxide material, including a cadmium stannate, an indium-doped cadmium oxide, or a tin-doped indium oxide or fluorine-doped tin oxide. A semiconductor bi-layer 230 can be deposited adjacent to transparent conductive oxide layer 220. Semiconductor bi-layer 230 can include semiconductor window layer 231 and semiconductor absorber layer 232. Semiconductor window layer 231 of semiconductor bi-layer 230 can be deposited adjacent to transparent conductive oxide layer 220, which can be annealed. Semiconductor window layer 231 can include any suitable window material, such as cadmium sulfide, and can be formed by any suitable deposition method, such as sputtering or vapor transport deposition or closed space sublimation. Semiconductor absorber layer 232 can be deposited adjacent to semiconductor window layer 231. Semiconductor absorber layer 232 can be deposited on semiconductor window layer 231. Semiconductor absorber layer 232 can be any suitable absorber material, such as cadmium telluride, and can be formed by any suitable method, such as sputtering or vapor transport deposition or closed space sublimation.

Back contact 240 can be deposited adjacent to semiconductor absorber layer 232. Back contact layer 240 can be deposited adjacent to semiconductor bi-layer 230. Back contact layer 240 can include a back contact material that can reduce the back-contact barrier effect compared to a metal back contact. The back contact material can include an indium nitride.

Back contact layer 240 can be deposited by activation reactive evaporation (ARE). In certain embodiments, indium nitride (InN) films can be deposited by activated reactive evaporation (ARE) process using parallel plate coupled with nitrogen plasma and evaporation of pure indium powder by resistive or e-beam heating. The depositions can be carried out by varying RF plasma power with radio frequency source of 13.56 MHz. The process can be maintained at room temperature at a nitrogen gas pressure of 1.06×10⁻¹ Pa (8×10⁻⁴ Torr). The back contact layer can also be deposited by chemical vapor deposition (CVD), low-pressure organometallic chemical vapor deposition (LPOCVD), or any other suitable vapor transition deposition (VTD) techniques.

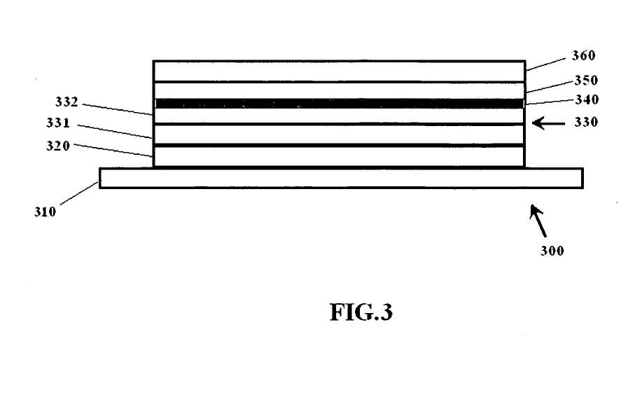

Referring to FIG. 3, a photovoltaic device 300 can include a transparent conductive oxide layer 320 deposited adjacent to a substrate 310. Transparent conductive oxide layer 320 can be deposited on substrate 310 by sputtering or evaporation. Substrate 310 can include a glass, such as soda-lime glass. Transparent conductive oxide layer 320 can include any suitable transparent conductive oxide material, including a cadmium stannate, an indium-doped cadmium oxide, or a tin-doped indium oxide or fluorine-doped tin oxide. A semiconductor bi-layer 330 can be formed or deposited adjacent to annealed transparent conductive oxide layer 320. Semiconductor bi-layer 330 can include semiconductor window layer 331 and semiconductor absorber layer 332. Semiconductor window layer 331 of semiconductor bi-layer 330 can be deposited adjacent to annealed transparent conductive oxide layer 320. Semiconductor window layer 331 can include any suitable window material, such as cadmium sulfide, and can be formed by any suitable deposition method, such as sputtering or vapor transport deposition or closed space sublimation. Semiconductor absorber layer 332 can be deposited adjacent to semiconductor window layer 331. Semiconductor absorber layer 332 can be deposited on semiconductor window layer 331. Semiconductor absorber layer 332 can be any suitable absorber material, such as cadmium telluride, and can be formed by any suitable method, such as sputtering or vapor transport deposition or closed space sublimation. Back contact 350 can be deposited adjacent to semiconductor absorber layer 332. Back contact 350 can be deposited adjacent to semiconductor bi-layer 230. Back contact 350 can include an indium nitride 340. Back contact 350 can be deposited by sputtering process. Back support 360 can be positioned adjacent to back contact 350.

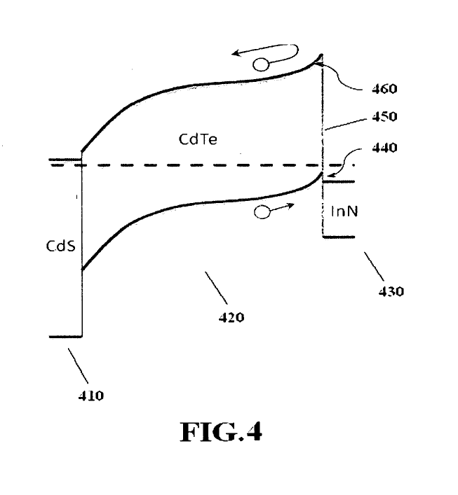

Referring to FIG. 4, a photovoltaic device having a cadmium sulfide layer as semiconductor window layer 410 and a cadmium telluride layer as semiconductor absorber layer 420 can have back contact layer 430 that includes an n-type indium nitride layer. Adding n-type indium nitride at back contact 430 can enhance device performance through several mechanisms. First, the resistance of back contact 430 can be reduced by elimination of Schottky barrier for the holes. Instead recombination path 440 can be created to allow the holes collected in the accumulation layer formed on the cadmium telluride side of hetero-interface 450 to recombine with the electrons accumulated on the indium nitride side of interface 450 causing useful current in the external circuit. Second, the collection losses of a solar cell can be reduced by conduction band bending on the cadmium telluride side of interface 450 that can effectively form electron reflector 460 by creating electric field that suppresses electron flow toward the back contact. Such configuration also allows reducing the thickness of CdTe layer 420 without reduction in the collection efficiency.

In certain embodiments, with the improved back contact, the average cell performances show notable improvement compared to the control group (with metal back contact): voltage V_{OC} can increased from about 780 mV to about 810 mV; efficiency can increased from about 11% to about 11.7%. The sheet resistance of InN film can be in the range from about 6000 ohms/square to about 8000 ohms/square. The resistivity of indium nitride film can be in the range from about 0.012 ohm-cm to about 0.014 ohm-cm. The carrier concentration of InN film can be in the range from about 2.6×10²⁰ cm⁻³ to about 3.0×10²⁰ cm⁻³. The electron mobility of indium nitride film can be in the range from about 1.5 cm²/v·s to about 1.9 cm²/v·s.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A photovoltaic device comprising:
a substrate;
a transparent conductive oxide layer adjacent to the substrate;
a semiconductor layer adjacent to the transparent conductive oxide layer, the semiconductor layer comprising a semiconductor absorber layer and a semiconductor window layer; and
a back contact layer adjacent to the semiconductor layer, wherein the back contact layer comprises an indium nitride.

2. The photovoltaic device of claim 1, wherein the device has a reduced back-contact barrier effect compared to a metal back contact.

3. The photovoltaic device of claim 1, further comprising a back support adjacent to the back contact.

4. The photovoltaic device of claim 1, wherein the substrate comprises a glass.

5. The photovoltaic device of claim 1, wherein the semiconductor window layer comprises a cadmium sulfide.

6. The photovoltaic device of claim 1, wherein the semiconductor absorber layer comprises a cadmium telluride.

7. The photovoltaic device of claim 1, wherein the transparent conductive oxide layer comprises a zinc oxide.

8. The photovoltaic device of claim 1, wherein the transparent conductive oxide layer comprises a tin oxide.

9. The photovoltaic device of claim 1, wherein the transparent conductive oxide layer comprises a cadmium stannate.

10. A method of manufacturing a photovoltaic device comprising the steps of:
depositing a transparent conductive oxide layer adjacent to a substrate;
depositing a semiconductor window layer adjacent to the transparent conductive oxide layer;
depositing a semiconductor absorber layer adjacent to the semiconductor window layer; and
depositing a back contact layer adjacent to the semiconductor absorber layer, wherein the back contact layer includes an indium nitride.

11. The method of claim 10, wherein the device has a reduced back-contact barrier effect compared to metal back contact.

12. The method of claim 10, further comprising attaching a back support adjacent to the back contact layer.

13. The method of claim 10, wherein the step of depositing the back contact layer comprises evaporation.

14. The method of claim 10, wherein the step of depositing the back contact layer comprises activation reactive evaporation.

15. The method of claim 10, wherein the step of depositing the back contact layer comprises chemical vapor deposition.

16. The method of claim 10, wherein the step of depositing the back contact layer comprises low-pressure organometallic chemical vapor deposition.

17. The method of claim 10, wherein the step of depositing the back contact layer comprises sputtering.

18. The method of claim 10, wherein the step of depositing the back contact layer comprises reactive sputtering.

19. The method of claim 10, wherein the semiconductor window layer comprises a cadmium sulfide and the semiconductor absorber layer comprises a cadmium telluride.

20. The method of claim 10, wherein the transparent conductive oxide layer comprises a zinc oxide, a tin oxide, or a cadmium stannate.
